(19) United States
(12) Patent Application Publication
(10) Pub. No.: US 2012/0104454 A1
(43) Pub. Date: May 3, 2012

(54) OPTICAL DEVICE, PROCESS FOR FABRICATING IT AND AN ELECTRONIC PACKAGE COMPRISING THIS OPTICAL DEVICE

(75) Inventor: Romain Coffy, Saint Martin Le Vinoux (FR)

(73) Assignee: STMICROELECTRONICS (GRENOBLE 2) SAS, Grenoble (FR)

(21) Appl. No.: 13/241,382

(22) Filed: Sep. 23, 2011

(30) Foreign Application Priority Data
Oct. 28, 2010 (FR) 1058895

(51) Int. Cl. H01L 33/52; H01L 33/48; H01L 31/18; H01L 31/0203

(52) U.S. Cl. 257/100; 257/433; 438/26; 438/64; 257/E33.056; 257/E33.059; 257/E31.117

(57) ABSTRACT

An optical device includes at least one optical die (4) that is embedded, at least peripherally, in a plate made of an encapsulation material so that the optical die may transmit light, from one side of the plate to the other. An electronic package is formed by a semiconductor device which includes at least one optical, integrated-circuit chip with the optical device placed so that the optical die lies above optical integrated circuits formed in or on the integrated circuit chip. The optical device is attached onto the semiconductor device.

### PRIORITY CLAIM

This application claims priority from French Application for Patent No. 1058895 filed Oct. 28, 2010, the disclosure of which is hereby incorporated by reference.

### TECHNICAL FIELD

The present invention relates to the field of optical devices and semiconductor devices equipped with optical devices.

### BACKGROUND

Electronic packages are known which comprise integrated-circuit chips comprising optical elements such as light emitters or detectors fitted on plates providing support and electrical connection, and optical elements such as optical dies or lenses placed in front of the optical elements of the chips and borne by collars fixed onto the supporting plates. Such packages are however not well suited when it is a question of providing electronic packages that must hold several neighboring integrated-circuit chips.

### SUMMARY

Firstly, an optical device is provided. This optical device comprises at least one optical die and a plate made of an encapsulation material in which the optical die is embedded, at least peripherally, a first face of the plate and a first face of the optical die lying in the same plane, a second face of the optical die opposite its first face being at least partially exposed, so that the optical die may transmit light, from one side of the plate to the other.

The optical device may comprise an optical element placed on the second-face side of the optical die and optically associated with the latter.

The optical device may comprise, in the plate, two optical dies.

The optical device may comprise, in the plate, an optical die and a through-hole, and an optical element associated with this hole.

Also provided is a process for fabricating an optical device. This process comprises: placing a first face of at least one optical die on a surface of a mold; and encapsulating, on said surface of the mold, the optical die with an encapsulation material, so as to obtain an intermediate overmolded layer that is thicker than the optical die and that has a first face in the plane of the first face of the optical die.

The process also comprises: carrying out an operation for removing some of the encapsulation material from the second-face side of the intermediate layer opposite its first face, at least above at least one part of a second face of the optical die opposite its first face so as to expose this part, so as to obtain a plate in which the optical die is embedded at least peripherally and so that the optical die may transmit light, from one side of the plate to the other.

The process may comprise: carrying out an operation for removing and planarizing the encapsulation material from the second-face side of the intermediate layer opposite its first face, at least down to the second face of the optical die.

The process may comprise: producing an aperture in the intermediate layer at least above at least one part of the second face of the optical die, so as to obtain a plate containing this aperture.

The process may comprise: fitting an optical element above the second face of the optical die.

The process may comprise: encapsulating the optical die on the surface of a mold having a protruding part so as to create a void in the intermediate layer, the removal operation opening this void so as to form a through-hole in the plate.

The process may comprise: fitting an optical element above or into the through-hole in the plate.

An electronic package is also provided. This electronic package comprises a semiconductor device comprising at least one integrated-circuit chip containing, on one side, at least some optical integrated circuits; an optical device placed so that the optical die lies above the integrated circuits; and a means for fixing the optical device onto the semiconductor device.

The electronic package may comprise a plate made of an encapsulation material in which the chip is embedded, at least peripherally, leaving exposed said integrated optical element, the plate of the semiconductor device being provided with means, for electrically connecting one face to the other, electrically connected to the chip.

The means for fixing the optical device onto the semiconductor device may be formed by an adhesive layer interposed between them.

The semiconductor device comprises at least one passive component connected to the electrical connection means.

The semiconductor device may comprise at least two optical, integrated-circuit chips, one chip of which comprises a light emitter and one chip of which comprises a light detector, and in which the optical device comprises a die above one of the chips and a die, or a hole associated with an optical element, above the other chip.

### BRIEF DESCRIPTION OF THE DRAWINGS

Optical devices and processes for fabricating the latter and electronic packages will now be described by way of non-limiting examples, illustrated by the drawings in which:

FIG. 1 shows a cross section of an optical device;

FIG. 2 shows a step in the fabrication of the optical device in FIG. 1;

FIG. 3 shows another step in the fabrication of the optical device in FIG. 1;

FIG. 4 shows another step in the fabrication of the optical device in FIG. 1;

FIG. 5 shows a variant embodiment of the optical device in FIG. 1;

FIG. 6 shows another variant embodiment of the optical device in FIG. 1;

FIG. 7 shows a cross section of another optical device;

FIG. 8 shows a variant embodiment of the optical device in FIG. 7;

FIG. 9 shows a cross section of another optical device;

FIG. 10 shows a step in the fabrication of the optical device in FIG. 9;

FIG. 11 shows another step in the fabrication of the optical device in FIG. 9;

FIG. 12 shows another step in the fabrication of the optical device in FIG. 9;

FIG. 13 shows a variant embodiment of the optical device in

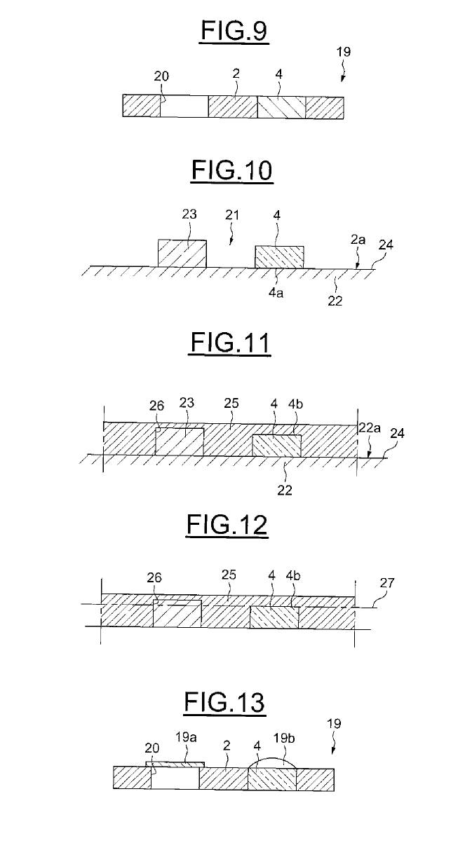

FIG. 9; and

FIG. 14 shows a cross section of an electronic package.

### DETAILED DESCRIPTION OF THE DRAWINGS

Firstly, optical devices and operations allowing their fabrication will be described.

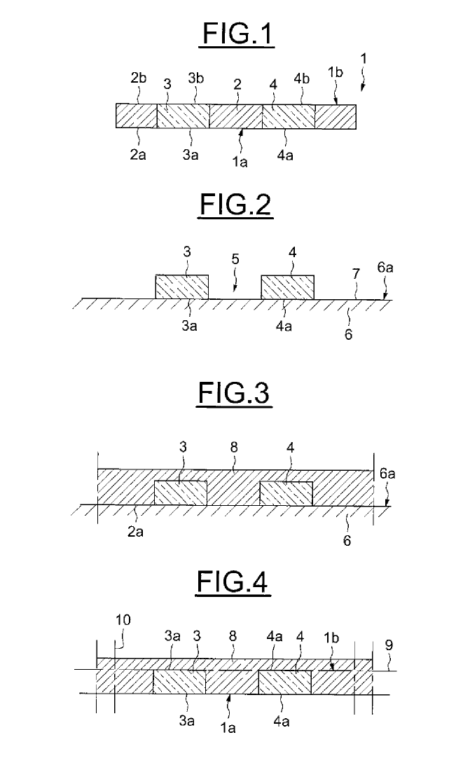

With reference to FIG. 1, it may be seen that an optical device 1 comprises a plate 2 made of an encapsulation material, for example an epoxy resin, in which are embedded, for example, two optical dies 3 and 4 which may be cylindrical, rectangular or square. The optical device 1 could comprise a single die or more than two dies.

The optical dies 3 and 4 have first faces 3a and 4a which lie in the same plane as a first face 2a of the plate 2, forming a back face 1a of the optical device 1, and second faces 3b and 4b which lie in the same plane as a second face 2b of the plate 2, forming a front face 1b of the optical device 1, these back and front faces 1a and 1b being parallel. Thus, the plate 2 encapsulates or envelops the periphery of the optical dies 3 and 4 and the back face forms a fitting face as will be seen below.

The optical dies 3 and 4 may be made of glass or of a plastic. They may be transparent or be treated so as to form filters or lenses.

In order to fabricate the optical device 1, it is possible to proceed as follows.

As illustrated in FIG. 2, optical dies 3 and 4 are placed in a location 5 on a flat surface 6a of a mold 6, their first faces 3a and 4a being against this surface 6a. In order to hold the optical dies 3 and 4 in place, the surface 5a of the mold 5 may be covered with a peelable adhesive 7. For the purpose of a batch fabrication, other optical dies 3 and 4 may be placed in other locations 5 on the flat surface 6a of the mold 6.

Next, as illustrated in FIG. 3, a layer 8 of a liquid encapsulation material is poured or overmolded onto the surface 6a of the mold 6, this encapsulation material being thicker than the optical dies 3 and 4 and covering the latter. The first face 2a of the plate 2 to be fabricated is then formed against the surface 6a of the mold 6, in the same plane as the first faces 3a and 4a of the optical dies 3 and 4.

Next, after the encapsulation material 8 has been cured and extracted from the mold 5, as illustrated in FIG. 4, part of the layer 8, on the side opposite the first face 2a, is removed, down to the level 9 of the second faces 3b and 4b of the optical dies 3 and 4 so as to expose these second faces 3b and 4b. This operation may be carried out using chemical, mechanical or mechanical-chemical erosion (for example, a machining process, a grinding process, a polishing process or perhaps an etching process, or some combination).

If one of the optical dies 3 and 4 were thicker than the other, this removal operation would also consist in removing part of the thickest optical die, at least down to the level of the thinnest optical die.

In the case of a batch fabrication, the optical devices 1 to be obtained may be singulated for example by sawing along scribe lines 10.

The optical device 1 may be finished with an optical element optically associated with one of the optical dies 3 and 4 or with optical elements associated respectively with these optical dies.

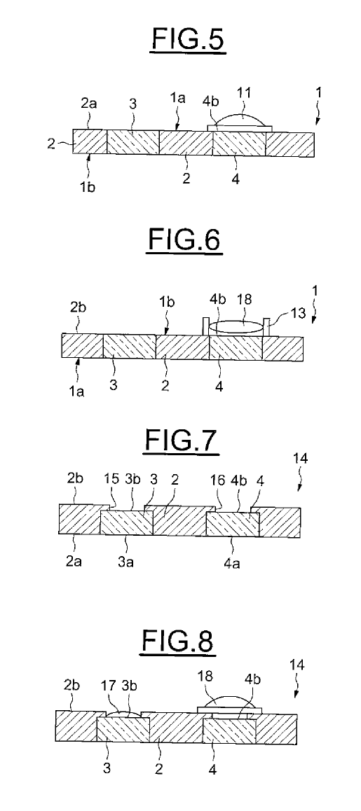

According to one variant shown in FIG. 5, a lens 11 may be provided and fixed onto the face 1b opposite the fitting face 1a, for example by bonding of a flat face of the latter onto the second face 4b of the optical die 4 and/or onto the edge of the second face 2a of the plate 2 surrounding the periphery of the optical die 4.

According to another variant shown in FIG. 6, a lens 12 may be borne by a collar 13, this collar 13 being fixed, for example by bonding, onto the second face 4b of the optical die 4 and/or onto the second face 2a of the plate 2.

With reference to FIG. 7, an optical device 14 may be seen that differs from the optical device 1, in that the second face 2b of its plate 2 is located above and distant from the second faces 3b and 4b of the optical dies 3 and 4 and in that the plate 2 has apertures 15 and 16 which are formed in its second face 2b above the second faces 3b and 4b of the optical dies 3 and 4 so as to partially or totally expose these second faces 3b and 4b.

To fabricate the optical device 14, with reference to FIG. 3, apertures 15 and 16 may be produced, after the layer 8 which forms the plate 2 has been cured and extracted from the mold 6, using chemical, mechanical or mechanical-chemical erosion or using the action of a laser beam. Furthermore, the face 2a of the plate 2 may be planarized.

As was the case for the optical device 1, the optical device 14 may furthermore be equipped with an optical element optically associated with one of the optical dies 3 and 4 or with optical elements associated respectively with these optical dies.

For example, as illustrated in FIG. 8, a lens 17 may be placed in front of and fixed directly to the second front face 3b of the optical die 3, in the aperture 15 of the plate 2, and a lens 18, placed in front of the die 4, may be fixed directly to the second face 2b of the plate 2, distant from the second face 4b of the optical die 4. The lenses 17 and 18 may have different optical properties. One and/or the other of the lenses 17 and 18 could be replaced by the lens 12, borne by the collar 13, in FIG. 6.

Shown in FIG. 9 is an optical device 19 that differs from the optical device 1 in that there is no optical die 3 and in that the plate 2 has, instead, a through-hole 20.

To fabricate the optical device 19, it is possible to proceed as follows.

As illustrated in FIG. 10, an optical die 4 is placed in a location 21, or respectively in locations 21 in the case of a batch fabrication, on a flat surface 22a of a mold 22. In this location 21, the mold has a protruding part 23, the periphery of which corresponds to the through-hole 20 to be obtained, and has a greater thickness than the optical die 4. The surface 22a may be covered with a peelable adhesive 24.

Then, as illustrated in FIG. 11, as described above, a layer 25 of a liquid encapsulation material is poured onto the surface 22a of the mold 22, this layer 25 being thicker than the protruding part 23. The protruding part 23 of the mold 22 then forms a void 26 in the layer 25.

Next, after the encapsulation material 25 has been cured and extracted from the mold 22, a part of the layer 25, as illustrated in FIG. 12, is removed down to the level 27 of the second face 4b of the optical die 4 so as to expose this face 4b. This operation allows the front of the void 26 to be opened so as to form the through-hole 20. After sawing, singulated optical devices 19 are then obtained.

According to a variant embodiment, it is possible, as was the case for the example in FIG. 7, to produce apertures in the layer 25, above the optical die 4 and through this layer 25 above the void 26, so as to form a through-hole 20. In this case, the depth of the void 26 could be greater than, equal to or less than the thickness of the optical die 4.

As in the preceding examples, the optical device 19 may be finished with an optical element optically associated with the optical die 4 or with the through-hole 20, or with optical elements associated respectively with the optical die 4 and with the through-hole 20.

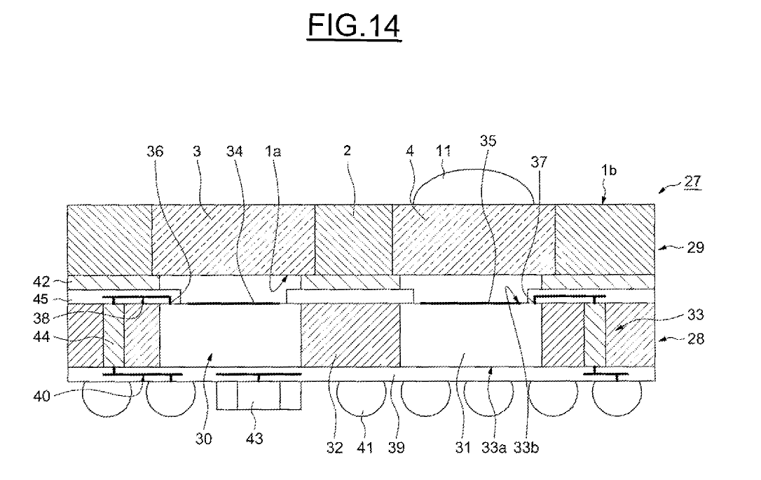

For example, as illustrated in FIG. 13, the optical device 19 could be equipped with a transparent protection sheet 19a in front of the through-hole 20 and with a lens 19b in front of the optical die 4. In a variant embodiment, the sheet 19a could be replaced by a lens and the lens 19b could be omitted. The sheet or the lens 19a could extend into or be placed in the through-hole 20.

With reference to FIG. 14, an electronic package 27 will now be described.

This electronic package 27 comprises a semiconductor device 28 and an optical device 29 which is optically associated with the semiconductor device 28.

The semiconductor device 28 comprises, for example, two integrated-circuit chips 30 and 31 which are embedded, peripherally, in an overmolded plate 32 made of an encapsulation material, for example of epoxy, so as to form a reconstituted wafer 33 the parallel front and back faces of which are defined by the front and back faces of the integrated-circuit chips 30 and 31 and of the plate 32. The semiconductor device 28 could comprise a single integrated-circuit chip or more than two integrated-circuit chips.

The chips 30 and 31 have, on or in their front faces, optical integrated circuits 34 and 35 and electrical connection pads 36 and 37 located around these integrated circuits 34 and 35. According to one variant embodiment, the integrated circuit 34 of the chip 30 may be a light emitter and the integrated circuit 35 of the chip 31 may be a light detector.

The semiconductor device 28 comprises a front layer 45 formed on the front face 33b of the wafer 33, which does not cover the integrated circuits 34 and 35 and in which is integrated a front electrical connection network 38. This electrical connection network 38 is selectively connected to the connection pads 36 and 37 of the chips 30 and 31.

The semiconductor device 28 also comprises a back layer 39 formed on the back face 33a of the wafer 33, in which a back electrical connection network 40 is integrated. This electrical connection network 40 is selectively connected to a plurality of external electrical connection bumps 41 placed on the back layer 39.

The semiconductor device 28 furthermore comprises a plurality of electrical connection vias 44 which extend through the plate 32 and which are selectively connected at one end to the electrical connection network 38, and at the other end to the electrical connection network 40.

Moreover, the semiconductor device 28 may be equipped with at least one passive component 43 fixed onto the back layer 39 and selectively connected to the back electrical connection network 40, the thickness of this passive component 43 being at the most equal to the thickness of the external electrical connection bumps 41. In a variant embodiment, the passive component 43 could be embedded in the plate 32, in a position such that its face provided with electrical connection means would be on the face 33a of the plate 33, these connection means being connected to the connection network 40.

Thus, the chips 30 and 31, the external electrical connection bumps 41 and the passive component 43 can be selectively connected so as to supply the chips 30 and 31 with electrical power and to exchange electrical signals, for example with a printed circuit board to which the bumps 41 may be connected.

In a variant embodiment, the semiconductor device 28 could comprise at least one non-optical integrated-circuit chip, also connected to the electrical connection network 38.

The optical device 29 may be formed by any one of the optical devices 1, 14, or 19 described above, and assembled in the same way to the semiconductor device 28.

According to the example shown in FIG. 14, the optical device 29 is formed by the optical device 1 in FIG. 4.

According to this example, the back face 1a of the optical device 29 is fixed onto the front layer 45 by way of a local adhesion layer 42 which does not cover the integrated circuits 34 and 35. Nevertheless, if this layer 42 is made of a transparent adhesive, the integrated circuits 34 and 35 could be covered.

The optical device 29 and the semiconductor device 28 are assembled in relative positions such that the optical die 3 is located above the integrated circuits 34, forming an emitter, of the chip 30 and the optical die 4 equipped on its front with the lens 11 is located above the integrated circuits 35, forming a detector, of the chip 31. Other arrangements are possible.

To fabricate the package 27, the semiconductor device 28 and the optical device 29 may be assembled in several ways.

Devices 28 and 29 may be individually assembled.

Individual devices 28 may be assembled in locations corresponding respectively to devices 29 in a wafer comprising a plurality of devices 29, and vice versa, this wafer being subsequently sawn so as to singulate the packages.

Wafers comprising respectively pluralities of devices 28 and 29 may be assembled in a suitable position, these wafers being subsequently sawn so as to singulate the various packages 27 to be obtained.

The present invention is not limited to the examples described above. Many other variant embodiments, for example combining the devices described differently, are possible, without departing from the scope defined by the appended claims.

What is claimed is:

1. Optical device comprising:
at least one optical die;
a plate made of an encapsulation material in which the optical die is at least peripherally embedded;
wherein a first face of the plate and a first face of the optical die lie in a same plane to define a back face of said optical device, said back face comprising a mounting surface;
wherein a second face of the optical die opposite said first face of the optical die is at least partially exposed, so that the optical die may transmit light, from one side of the plate to another side of the plate.

2. The optical device according to claim 1, comprising an optical element placed over the second face side of the optical die and optically associated with the latter.

3. The optical device according to claim 1, comprising at least two optical dies at least peripherally embedded in the plate.

4. The optical device according to claim 1, comprising a through hole formed in the plate, and an optical element placed over or in the through hole and optically associated with said through hole.

5. The optical device according to claim 1, wherein said mounting surface is adapted for mounting said optical device to a semiconductor device.

6. A process for fabricating an optical device, comprising:
placing a first face of at least one optical die on a surface of a mold;
encapsulating, on said surface of the mold, the optical die with an encapsulation material, so as to obtain an intermediate overmolded layer that is thicker than the optical die and having a first face of the overmolded layer in a same plane as the first face of the optical die to define a back face of said optical device, said back face comprising a mounting surface; and
carrying out an operation to remove some of the encapsulation material from a second-face side of the intermediate overmolded layer opposite said first face of the intermediate overmolded layer, said removal of encapsulation material being performed at least above at least one part of a second face of the optical die opposite said first face of the optical die so as to expose said at least one part and obtain a plate in which the optical die is at least peripherally embedded and so that the optical die may transmit light, from one side of the plate to another side of the plate.

7. The process according to claim 6, wherein carrying out the operation to remove comprises planarizing the encapsulation material from the second-face side of the intermediate overmolded layer at least down to the second face (4b) of the optical die.

8. The process according to claim 6, further comprising: producing an aperture in the intermediate overmolded layer at least above at least one part of the second face of the optical die, so as to obtain a plate containing this aperture.

9. The process according to claim 8, further comprising: fitting an optical element above or in the aperture in the intermediate overmolded layer.

10. The process according to claim 6, further comprising: fitting an optical element above the at least one optical die.

11. The process according to claim 6, wherein encapsulating comprises: encapsulating the optical die on the surface of the mold having a protruding part so as to create a void in the intermediate overmolded layer, the removal operation opening this void so as to form a through-hole in the plate.

12. The process according to claim 11, further comprising: fitting an optical element above or in the through-hole in the plate.

13. The process according to claim 11, wherein said mounting surface is adapted for mounting said optical device to a semiconductor device, further comprising mounting said optical device to said semiconductor device.

14. Electronic package comprising:
a semiconductor device comprising at least one integrated-circuit chip containing, on one side, at least some optical integrated circuits and having a front face;
an optical device including an optical die, wherein the optical device is placed so that the optical die lies above the front face of the at least one integrated circuit; and
material configured to fixing the optical device onto the front face of the semiconductor device; wherein the optical device comprises:
a plate made of an encapsulation material and configured to at least peripherally embed the optical die;
wherein a first face of the plate and a first face of the optical die lie in a same plane to define a back face of said optical device, said back face comprising a mounting surface to be mounted to the front face of the semiconductor device using said fixing material;
wherein a second face of the optical die opposite said first face of the optical die is at least partially exposed, so that the optical die may transmit light, from one side of the plate to another side of the plate.

15. The package according to claim 14, wherein the semiconductor device comprises a plate made of an encapsulation material in which the chip is at least peripherally embedded leaving exposed said integrated optical element, the plate of the semiconductor device being provided with a circuit configured to electrically connect one face to the other, and wherein the circuit is electrically connected to the chip.

16. The package according to claim 14, wherein said material for fixing the optical device onto the semiconductor device is formed by an interposed adhesive layer.

17. The package according to claim 14, further comprising at least one passive component connected to the circuit configured to electrically connect.

18. The package according to claim 14, wherein the semiconductor device comprises at least two optical, integrated-circuit chips.

19. The package according to claim 18, wherein one of the two chips comprises a light emitter and another of the two chips comprises a light detector.

20. The package according to claim 18, wherein the optical device comprises a first die positioned in the package above one of the two chips and a second die positioned in the package above the another of the two chips.

21. The package according to claim 18, wherein the optical device comprises said optical die positioned in the package above one of the two chips, and further including a through hole formed in the plate of the encapsulation material and positioned in the package above the another of the two chips.
